(19) United States
(12) Patent Application Publication
(10) Pub. No.: US 2003/0184979 A1
(43) Pub. Date: Oct. 2, 2003

(54) Circuit board free of photo-sensitive material and fabrication method of the same

(75) Inventors: Chung-Che Tsai, Hsinchu (TW); Jin-Chuan Bai, Hsinchu (TW)

Correspondence Address: EDWARDS & ANGELL, LLP, P.O. BOX 9169, BOSTON, MA, 02209, US

(73) Assignee: UltraTera Corporation, Hsinchu (TW)

(21) Appl. No.: 10/176,168

(22) Filed: Jun. 20, 2002

(30) Foreign Application Priority Data
Mar. 27, 2002 (TW) 91105980

(51) Int. Cl. H05K 1/00

(52) U.S. Cl. 361/748

(57) ABSTRACT

A circuit board free of photo-sensitive material and a fabrication method thereof are proposed, in which at least a surface of a core layer is formed with conductive traces thereon, and a photo-insensitive material is applied over the surface of the core layer in a manner as to hermetically encapsulate the conductive traces, with terminals of the conductive traces being exposed to outside of the photo-insensitive material, whereby solder balls, solder bumps or bonding wires can be bonded to the exposed terminals of the conductive traces, allowing the circuit board to be electrically connected to an external device or a chip by the solder balls, solder bumps or bonding wires. As the photo-insensitive material, instead of solder mask, is applied over the core layer, drawbacks of using conventional solder mask in prior art can be effectively eliminated for the above-fabricated circuit board.

### FIELD OF THE INVENTION

The present invention relates to circuit boards and fabrication methods thereof, and more particularly, to a circuit board formed with a plurality of conductive traces for establishing electrical connection between the circuit board and an external device, and a method for fabricating the circuit board.

### BACKGROUND OF THE INVENTION

A printed circuit board (PCB) used as a carrier for semiconductor packages or electronic components, or a substrate for accommodating semiconductor chips thereon, is basically structured with a core layer, on which a plurality of conductive traces are formed. Terminals of the conductive traces are defined with bond pads or bond fingers where solder balls, solder bumps or bonding wires are bonded, so as to electrically connect the semiconductor packages to the printed circuit board, and to electrically connect the semiconductor chips to the substrate.

The conductive traces formed on the substrate or printed circuit board (hereinafter generally referred to as “circuit board”), if exposed to the atmosphere, would be oxidized by moisture and air, and undesirably lead to electricity problems for the circuit board. During a solder-reflowing process, solder paste for attaching solder balls or bumps to bond pads of the circuit board, would be wetted to the exposed conductive traces; this may cause the occurrence of short circuit and incomplete electrical connection. Therefore, solder mask is usually applied over the core layer as to encapsulate the conductive traces. As solder mask is not solderable, during solder reflowing, solder paste would be only wetted to bond pads defined at terminals of the conductive traces, but not to the conductive traces encapsulated by the solder mask.

Solder mask applied on the core layer, is normally added with a photo-sensitive ingredient to become a photo-imageable dielectric material (PID), and this PID solder mask is not capable of being deposited with predetermined thickness by single-time spreading on the core layer. Therefore, solder mask needs to be printed or sprayed in multiple times on the core layer. After being oven-dried and cooled down, solder mask covered on bond pads and bond fingers is removed by exposure technology, so as to expose the bond pads and bond fingers to outside of the solder mask. Then, a high-temperature baking process is performed for firmly curing the solder mask.

However, the above conventional circuit board is inherent with significant drawbacks.

First, multiple-time applying of solder mask on the core layer easily brings air entering into the solder mask; if solder mask is retained with voids therein, during subsequent high-temperature processes, popcorn effect tends to take place and damages reliability of the circuit board.

Moreover, thickness of solder is hardly controlled by multiple times of printing or spraying; therefore, solder mask applied over the core layer would not achieve desirable planarity for the circuit board, which would adversely affect quality of electrical connection between electronic components or devices and the circuit board. For example, when an encapsulant is formed in a molding process for encapsulating semiconductor chips mounted on the circuit board with poor planarity, resin flash would easily occur around the encapsulant, and thus deteriorate appearance of fabricated products. In this case, if a deflash process is performed to remove resin flash, this would increase process complexity and fabrication costs.

In addition, as solder mask is conventionally added with photo-sensitive ingredients and acrylic resin, it leads to relatively low bondability between solder mask and a molding compound used for forming the encapsulant; thereby, fabricated products are easily subject to delamination problems under high temperature environment, which may greatly damage reliability of fabricated products. Moreover, conventional solder mask is also weak in bondability with copper-made conductive traces and resin compounds for making the core layer, and solder mask has relatively larger coefficient of thermal expansion (CTE), this would similarly cause delamination at interface between solder mask and the core layer. And, solder mask has high moisture absorbability, and thus moisture in air easily penetrates into solder mask, also leading to reliability concern of the circuit board.

Furthermore, the conventional circuit board with duel-layered structure is usually formed with vias, which penetrate through the circuit board for electrically interconnecting conductive traces formed on upper and lower surfaces of the core layer. However, since solder mask is not capable of filling into the vias, additional filling material is necessarily used for filling of the vias first, and then solder mask can be applied over the core layer. This therefore increases process complexity and costs of fabrication by additional processes of via filling.

### SUMMARY OF THE INVENTION

A primary objective of the present invention is to provide a circuit board free of photo-sensitive material and a fabrication method of the circuit board, whereby bondability between the circuit board and an encapsulating resin, and between internal components of the circuit board can be desirably increased, and the circuit board can be improved with its electricity and reduced in its moisture absorbability, thereby bettering overall reliability of the circuit board.

Another objective of the invention is to provide a circuit board free of photo-sensitive material and a fabrication method of the circuit board, whereby the circuit board is cost-effectively fabricated by simplified processes.

In accordance with the above and other objectives, the present invention proposes a circuit board free of photo-sensitive material, comprising: a core layer made of a first resin compound; a plurality of conductive traces formed on at least a surface of the core layer, each of the conductive traces being formed with a terminal; and at least a cover layer applied over the surface of the core layer where the conductive traces are formed, in a manner that the conductive traces are encapsulated by the cover layer, with the terminals of the conductive traces being exposed to outside of the cover layer, wherein the cover layer is made of a second resin compound.

The second resin compound for forming the cover layer, can be a single compound, such as epoxy resin, polyimide resin, BT (bismaleimide triazine) resin, FR4 (fiberglass-reinforced) resin, FR5 resin and so on, or a mixture of two or more compounds thereof, it should be understood that, the second resin compound is not particularly limited, and any photo-insensitive material or any material not containing a photo-sensitive ingredient is suitably applied herein. Preferably, the second resin compound has coefficient of thermal expansion similar to that of the first resin compound for forming the core layer. It is more preferable that the first and second resin compounds have the same coefficient of thermal expansion, whereby thermal stress generated under high temperature can be reduced to the minimum for a fabricated circuit board, and thus warpage or delamination of the circuit board is effectively prevented from occurrence.

Moreover, for bettering improvements rendered in this invention, acrylic resin can be excluded from consideration for use as the second resin compound.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a circuit board free of photo-sensitive material of the invention; and

FIGS. 2A-2C are cross-sectional schematic diagrams showing process steps involved in a fabrication method of a circuit board free of photo-sensitive material of the invention.

### DETAILED DESCRIPTION OF THE PREFERRED EMBODIMENT

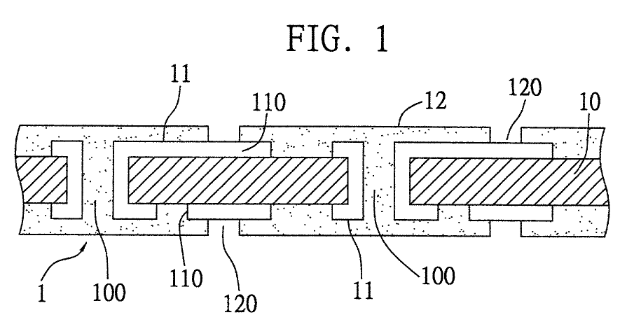

As shown in FIG. 1, a circuit board 1 free of photo-sensitive material proposed in the invention, comprises: a core layer 10; a plurality of conductive traces 11 formed on upper and lower surfaces of the core layer 10; and a cover layer 12 applied respectively over the upper and lower surfaces of the core layer 10 in a manner as to cover the conductive traces 11.

The core layer 10 is formed with a plurality of vias 100, which penetrate through the core layer 10 and electrically interconnect the conductive traces 11 on the upper and lower surfaces of the core layer 10. Since the vias 100 are formed by conventional technology, no further description thereto is to be here detailed. The core layer 10 is made of a material same as that used for a conventional circuit board, such as epoxy resin, polyimide resin, FR4 resin, etc. In the case of conductive traces 11 being formed only on a surface of the core layer 10, it is not necessary to form vias 100 through the core layer 10.

The conductive traces 11 are made by exposing, developing and etching copper films attached onto the core layer 10; since these processes are the same as for fabricating a conventional circuit board, no further description thereto is to be here detailed. Each of the conductive traces 11 is defined with a terminal 110, which is used as a bond pad or bond finger to be bonded with a solder ball, solder bump or bonding wire (not shown). In this embodiment, for example, terminals 110 of the conductive traces 11 on the upper surface of the core layer 10, can be bond fingers where bonding wires are bonded for electrically connecting a chip (not shown) mounted on the circuit board 1 to the circuit board 1; and terminals 110 on the lower surface of the core layer 10 are bond pads where solder balls are bonded for electrically connecting the chip to an external device.

The cover layer 12 is made of a single resin compound or a mixture of two or more resin compounds, such as epoxy resin, polyimide resin, BT resin, FR4 resin, FR5 resin and so on; these resin compounds are photo-insensitive or those not containing photo-sensitive ingredients; preferably, acrylic resin is not used for forming the cover layer 12. As the cover layer 12 is a photo-insensitive resin, the cover layer 12 applied over the core layer 10 can simultaneously fill into the vias 100; as such, the vias 100 are not necessarily filled by additional filling material as conventionally used in the prior art, making the circuit board 1 of the invention more cost-effectively fabricated by simplified processes. Moreover, further due to the cover later 12 being photo-insensitive or not containing photo-sensitive ingredients, the cover later 12 thus has different material characteristics from conventional solder mask; a table below illustrates characteristic differences between the cover layer and solder mask:

| | Material | |
|---|---|---|
| Characteristic | Cover layer | Solder mask |
| Tg (° C.) | 170 | 105 |
| Moisture absorbability | 0.5% | 0.84% |
| (85° C./85° C. 168H) | | |
| Bondability with copper | 3x | x |
| Bondability with an | 6x | 1x |
| encapsulating resin | | |
| Coefficient of thermal | 30 | 160 |
| expansion (CTE) at 121° C. | | |
| (ppm) | | |

With the above-listed characteristic differences, the cover layer and conventional solder mask would respectively achieve different performances in fabrication of circuit boards, as detailed in the following.

Tg: the cover layer made of a resin compound that is photo-insensitive or not containing photo-sensitive ingredients, has a glass transition temperature (Tg) much higher than that of conventional solder mask; therefore, the circuit board of the invention fabricated in the use of the cover layer, is relatively less liable to high temperature and thus better in reliability.

Moisture absorbability: moisture absorbability of the cover layer is much lower than that of conventional solder mask, making the circuit board of the invention effectively reduce in moisture absorption, thereby allowing reliability of fabricated circuit boards to be greatly improved.

Bondability with copper: the cover layer has its bondability with copper-made conductive traces to be three times larger than that between conventional solder mask and conductive traces, so that the cover layer of the invention can be more strongly bonded to conductive traces formed on the core layer of the circuit board, and thus, delamination between the cover layer and conductive traces is effectively prevented from occurrence, allowing reliability of the circuit board to be greatly improved.

Bondability with an encapsulating resin: bondability between the cover layer and the encapsulating resin is six times larger than that between conventional solder mask and the encapsulating resin; this therefore ensures firm bonding between the cover layer of the invention and the encapsulating resin to be free concern of delamination, thereby making fabricated products greatly assured in reliability.

CTE: coefficient of thermal expansion (CTE) of the cover layer is only one fifth of that of conventional solder mask, and thus significantly less thermal stress would be generated in the invention, whereby warpage or delamination of the circuit board of the invention can be effectively prevented from occurrence, and quality and reliability of fabricated circuit boards are greatly improved.

After the cover layer 12 is applied over the core layer 10, a plurality of openings 120 are formed through the cover layer 12 corresponding in position to the terminals 110 of the conductive traces 11, allowing the terminals 110 to be exposed to the openings 120, and solder balls, solder bumps and/or bonding wires can be bonded to the exposed terminals 110.

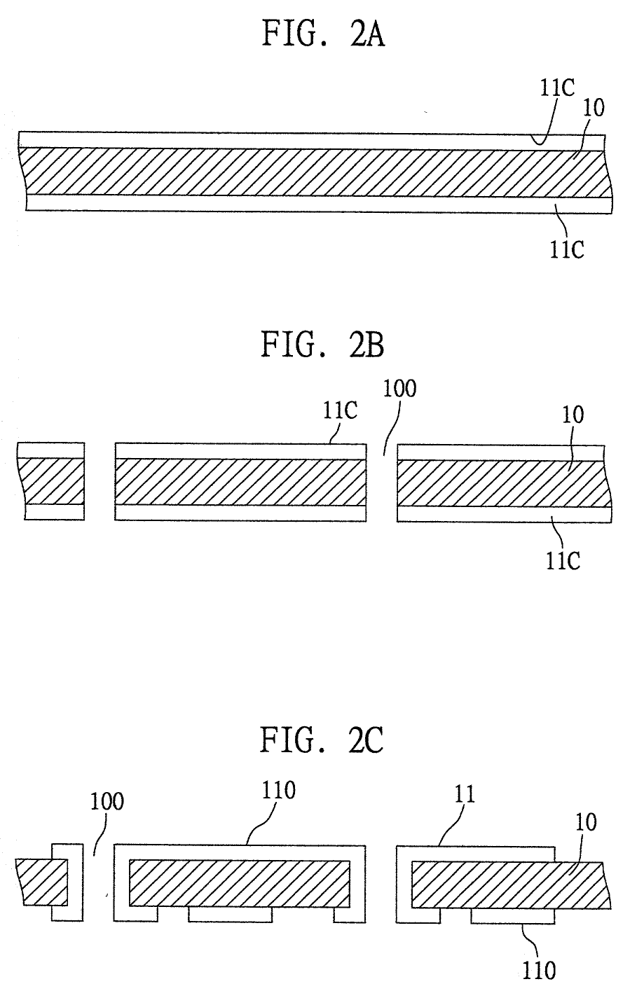

The circuit board 1 of the invention is fabricated by processes illustrated in FIGS. 2A to 2C.

Referring to FIG. 2A, the first step is to prepare a core layer 10, with a copper film 11c being respectively attached to upper and lower surfaces of the core layer 10. Then, referring to FIG. 2B, the core layer 10 is formed with a plurality of vias 100 that penetrate the copper films 11c on both the upper and lower surfaces of the core layer 10; and the vias 100 are conventionally plated with conductive metal as to electrically interconnect the copper films 11c on the upper and lower surfaces of the core layer 10. Since plating of the vias 110 with conductive metal is a conventional process, it is not to be further described herein. Next, referring to FIG. 2C, the copper films 11c are patterned by exposure, development and etching processes to form a plurality of conductive traces 11. Finally, as shown in FIG. 1, a cover layer 12 is respectively applied in single time of process over the upper and lower surfaces of the core layer 10 in a manner as to hermetically cover the conductive traces 11, with terminals 110 of the conductive traces 11 being exposed to outside of the cover layer 12. The cover layer 12 also fills into the vias 100 of the core layer 10, thereby making filling material within the vias 100 be part of the cover layer 12. This therefore completes the fabrication of the circuit board of the invention.

The cover layer 12 is applied over the core layer 10 by, but not limited to, conventional techniques such as molding, printing or pressing. And, a plurality of openings 120 are formed to penetrate through the cover layer 12 in a manner that, the terminals 110 of the conductive traces 11 can be exposed to the openings 120. Forming of the openings 120 can be simultaneously implemented during applying the cover layer 12 over the core layer 10, for example, by selectively removing the cover layer 12 through the use of grinding or laser technology. Alternatively, terminals 110 of the conductive traces 11 can be pre-covered with a chemically-etchable material, and the cover layer 12 is applied over the core layer 10 in a manner as not to cover the chemically-etchable material that is exposed to outside of the cover layer 12; this allows the exposed chemically-etchable material to be etched away by using chemical solvents without damaging the cover layer 12, such that the terminals 110 can be exposed to outside of the cover layer 12.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A circuit board free of photo-sensitive material, comprising:
a core layer made of a first resin compound;
a plurality of conductive traces formed on at least a surface of the core layer, each of the conductive traces being formed with a terminal; and
at least a cover layer applied over the surface of the core layer where the conductive traces are formed, in a manner that the conductive traces are encapsulated by the cover layer, with the terminals of the conductive traces being exposed to outside of the cover layer, wherein the cover layer is made of a photo-insensitive second resin compound.

2. The circuit board of claim 1, wherein the second resin compound is at least one selected from a group consisting of epoxy resin, polyimide resin, BT (bismaleimide triazine) resin, FR4 (fiberglass-reinforced) resin and FR5 resin.

3. The circuit board of claim 1, wherein the second resin compound is same as the first resin compound.

4. The circuit board of claim 1, wherein the second resin compound has coefficient of thermal expansion similar to that of the first resin compound.

5. The circuit board of claim 1, wherein the second resin compound has coefficient of thermal expansion same as that of the first resin compound.

6. The circuit board of claim 1, wherein if conductive traces are formed on both opposing surfaces of the core layer, the core layer is formed with a plurality of vias for electrically interconnecting the conductive traces on the opposing surfaces of the core layer.

7. The circuit board of claim 6, wherein the vias are filled with the second resin compound.

8. The circuit board of claim 1, wherein the terminals of the conductive traces are exposed by selectively removing the cover layer through the use of grinding technology.

9. The circuit board of claim 1, wherein the terminals of the conductive traces are exposed by selectively removing the cover layer through the use of laser technology.

10. A fabrication method of a circuit board free of photo-sensitive material, comprising the steps of:
preparing a core layer, the core layer being made of a first resin compound;
forming a plurality of conductive traces on at least a surface of the core layer, each of the conductive traces being formed with a terminal; and
applying at least a cover layer over the surface of the core layer where the conductive traces are formed, wherein the terminals of the conductive traces are exposed to outside of the cover layer, and the cover layer is made of a photo-insensitive second resin compound.

11. The fabrication method of claim 10, wherein the second resin compound is at least one selected from a group consisting of epoxy resin, polyimide resin, BT resin, FR4 resin and FR5 resin.

12. The fabrication method of claim 10, wherein the second resin compound is same as the first resin compound.

13. The fabrication method of claim 10, wherein the second resin compound has coefficient of thermal expansion similar to that of the first resin compound.

14. The fabrication method of claim 10, wherein the second resin compound has coefficient of thermal expansion same as that of the first resin compound.

15. The fabrication method of claim 10, wherein if conductive traces are formed on both opposing surfaces of the core layer, the core layer is formed with a plurality of vias for electrically interconnecting the conductive traces on the opposing surfaces of the core layer.

16. The fabrication method of claim 15, wherein the vias are filled with the second resin compound.

17. The fabrication method of claim 10, wherein the terminals of the conductive traces are exposed by selectively removing the cover layer through the use of grinding technology.

18. The fabrication method of claim 10, wherein the terminals of the conductive traces are exposed by selectively removing the cover layer through the use of laser technology.
